(19) United States
(12) Patent Application Publication
(10) Pub. No.: US 2007/0035929 A1
(43) Pub. Date: Feb. 15, 2007

(54) HEAT SINK WITH EMI SHIELDING WALLS

(75) Inventor: YUEH-HUA HSU, TUCHENG (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/308,059

(22) Filed: Mar. 4, 2006

(30) Foreign Application Priority Data
Aug. 12, 2005 (CN) 200510036592.3

(51) Int. Cl. H05K 7/20

(52) U.S. Cl. 361/704

(57) ABSTRACT

A heat sink (10) includes a base (14) and a plurality of heat dissipating protuberances (12). The base includes a plurality of shielding walls (142) and at least one receiving space (140) for receiving at least one electronic component (24). The shielding walls define the receiving space. The heat dissipating protuberances extend up from the base, for dissipating heat generated by the electronic component. The heat sink not only protects the electronic component from EMI, but also effectively dissipates heat generated by the electronic component.

### FIELD OF THE INVENTION

The present invention relates to heat sinks, and particularly to a heat sink that provides EMI shielding.

### DESCRIPTION OF RELATED ART

FIG. 4 is an isometric view of a conventional heat sink 40. The heat sink 40 can be mounted on an electronic component (not shown). The heat sink 40 comprises a plurality of heat fins 42 for dissipating heat generated by the electronic component. However, the electronic component generally comprises high frequency circuits (HFC), digital signal circuits (DSC), and analog signal circuits (ASC). Electromagnetic Interference (EMI) often occurs between neighboring electronic components due to inductive coupling. In addition, the heat sink 40 does not shield the electronic component from external EMI. Therefore, the effective performance of the electronic component may be interrupted, obstructed, or degraded by EMI.

Therefore, a heretofore unaddressed need exists in the industry to overcome the aforementioned deficiencies and inadequacies.

### SUMMARY OF INVENTION

In an exemplary embodiment, a heat sink comprises a base and a plurality of heat fins. The base comprises a plurality of shielding walls and at least one receiving space for receiving an electronic component. The shielding walls define the receiving space. The heat fins extend from the base, for dissipating heat generated by the electronic component. The heat sink not only protects the electronic component from EMI, but also effectively dissipates heat generated by the electronic component.

Other advantages and novel features will become more apparent from the following detailed description when taken in conjunction with the accompanying drawings, in which:

### BRIEF DESCRIPTION OF DRAWINGS

FIG. 1 is an exploded, isometric view of a heat sink in accordance with an exemplary embodiment of the present invention, together with a circuit board;

FIG. 2 is an isometric, inverted view of the heat sink of FIG. 1;

FIG. 3 is an assembled view of FIG. 1; and

FIG. 4 is an isometric view of a conventional heat sink.

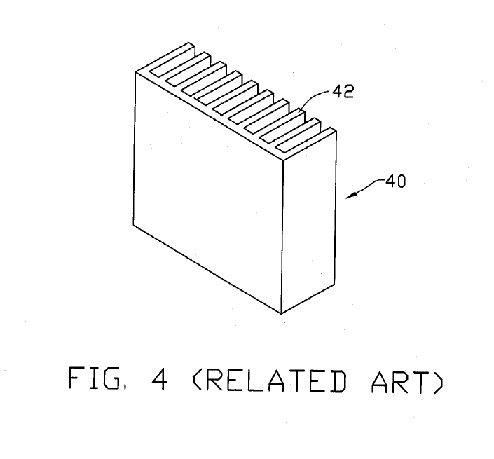

### DETAILED DESCRIPTION

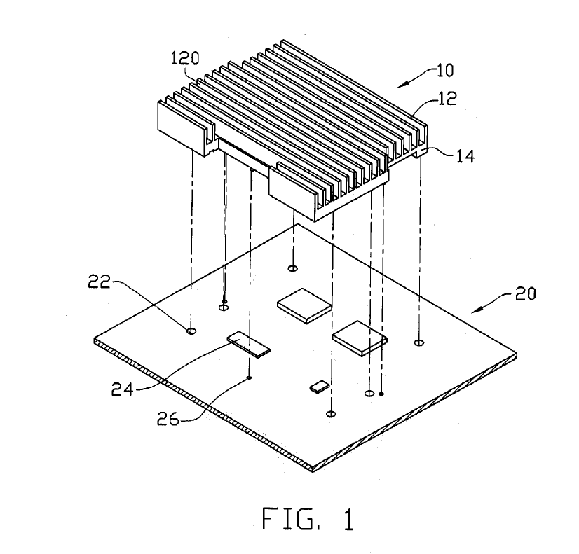

Referring to FIG. 1, a heat sink 10 of an exemplary embodiment of the present invention is mounted on a circuit board 20, such as a printed circuit board.

The circuit board 20 comprises a plurality of electronic components 24, a plurality of first mounting holes 22, and a plurality of locating holes 26. The first mounting holes 22 and the locating holes 26 are defined in a periphery of the circuit board 20 around the electronic components 24.

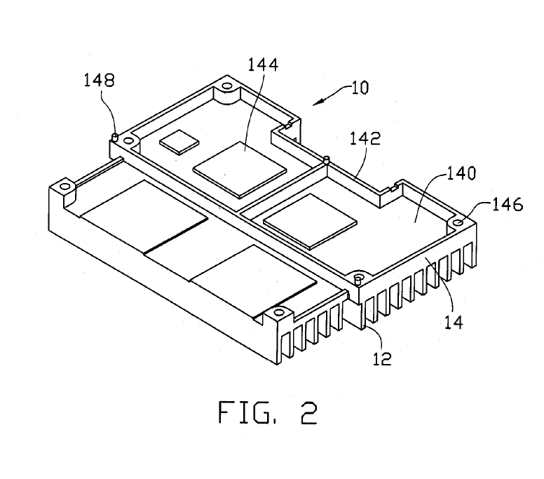

Referring also to FIG. 2, the heat sink 10 includes a plurality of heat fins 12 and a base 14. The heat fins 12 are integrally formed with the base 14, and are perpendicular to the base 14. A groove 120 is defined between every two adjacent heat fins 12. The base 14 includes a plurality of shielding walls 142. A plurality of receiving spaces 140 are defined by the shielding walls 142. The electronic components 24 are received in the corresponding receiving spaces 140 when the heat sink 10 is mounted on the circuit board 20. In the exemplary embodiment, there are three receiving spaces 140. In alternative embodiments, the number of receiving spaces 140 can vary from one to many according to the needs of particular applications. At least one projecting portion 144 protrudes from a main part of the base 14 into each receiving space 140, the projecting portions 144 corresponding to the electronic components 24 of the circuit board 20. The base 14 defines a plurality of second mounting holes 146 corresponding to the first mounting holes 22 of the circuit board 20. The base 14 comprises a plurality of posts 148 protruding down from the shielding walls 142 toward the circuit board 20, the posts 148 corresponding to the locating holes 26 of the circuit board 20. A plurality of fasteners such as bolts, (not shown) are provided for extending through the first and second mounting holes 22,146 and thereby fixing the heat sink 10 on the circuit board 20.

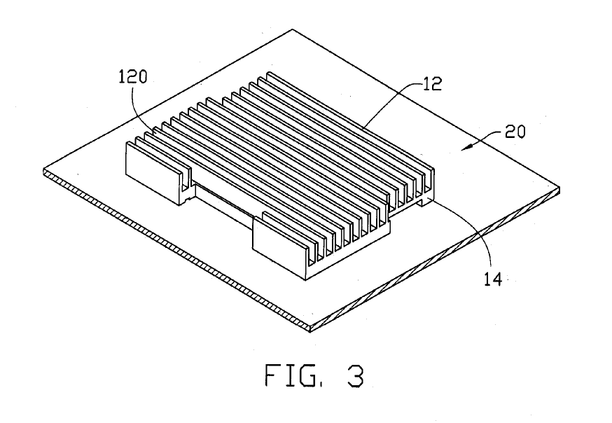

Referring also to FIG. 3, in assembly, the posts 148 of the heat sink 10 are inserted into the corresponding locating holes 26 of the circuit board 20. The fasteners are extended through the second mounting holes 146 of the heat sink 10 and threadedly received in the first mounting holes 22 of the circuit board 20. Thus, the heat sink 10 is securely mounted on the circuit board 20. In this position, the electronic components 24 of the circuit board 20 are located in the receiving spaces 140. The projecting portions 144 of the heat sink 10 abut the corresponding electronic components 24. Thereby, heat generated by the electronic components 24 can be dissipated by the heat fins 12 effectively.

Because the heat sink 10 comprises the heat fins 12 and the receiving spaces 140, the heat sink 10 not only protects the electronic components 24 received in the receiving spaces 140 from EMI, but also can effectively dissipate heat generated by the electronic components 24.

In alternative embodiments, the heat fins 12 may instead be heat pins, heat plates or other heat dissipating structure known in the art.

While exemplary embodiments have been described above, they should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A heat sink, comprising:
a base comprising a plurality of shielding walls and at least one receiving space for receiving at least one electronic component, the shielding walls defining the receiving space; and
a plurality of heat dissipating protuberances for dissipating heat generated by the electronic component, the heat dissipating protuberances extending up from the base.

2. The heat sink as claimed in claim 1, wherein the base is integrally formed with the heat dissipating protuberances.

3. The heat sink as claimed in claim 1, wherein at least one projecting portion protrudes down from a part of the base into the receiving space.

4. The heat sink as claimed in claim 1, wherein a groove is defined between every two adjacent heat dissipating protuberances.

5. The heat sink as claimed in claim 1, wherein the base further comprises a plurality of posts protruding down from a border thereof.

6. The heat sink as claimed in claim 1, wherein the heat dissipating protuberances are heat fins.

7. The heat sink as claimed in claim 1, wherein the heat dissipating protuberances are heat pins.

8. The heat sink as claimed in claim 1, wherein the heat dissipating protuberances are heat plates.

9. An electronic device assembly comprising:
a circuit board comprising at least one electronic component; and a heat sink comprising:
a base comprising a plurality of shielding walls and at least one receiving space for receiving the electronic component, the shielding walls defining the receiving space; and
a plurality of heat dissipating protuberances for dissipating heat generated by the electronic component, the heat dissipating protuberances extending up from the base.

10. The electronic device assembly as claimed in claim 9, wherein the base is integrally formed with the heat dissipating protuberances.

11. The electronic device assembly as claimed in claim 9, wherein at least one projecting portion protrudes down from a part of the base into the receiving space.

12. The electronic device assembly as claimed in claim 9, wherein a groove is defined between every two adjacent heat dissipating protuberances.

13. The electronic device assembly as claimed in claim 9, wherein the base further comprises a plurality of posts protruding down from a border thereof toward the circuit board.

14. The electronic device assembly as claimed in claim 9, wherein the circuit board defines a plurality of first mounting holes, and the heat sink defines a plurality of second mounting holes corresponding to the first mounting holes.

15. The electronic device assembly as claimed in claim 9, wherein the heat dissipating protuberances are heat fins.

16. The electronic device assembly as claimed in claim 9, wherein the heat dissipating protuberances are heat pins.

17. The electronic device assembly as claimed in claim 9, wherein the heat dissipating protuberances are heat plates.
